(19) United States
(12) Patent Application Publication
(10) Pub. No.: US 2025/0331431 A1
(43) Pub. Date: Oct. 23, 2025

(54) Inducing Cracks in Thin Films

(71) Applicant: UCL Business Ltd, London (GB)

(72) Inventors: Yaqi LI, Harrow (GB); Pavlo ZUBKO, Cambridge (GB)

(21) Appl. No.: 18/643,607

(22) Filed: Apr. 23, 2024

(51) Int. Cl. H10N 70/00

(52) U.S. Cl. CPC H10N 70/041; H10N 70/883

(57) ABSTRACT

This disclosure provides a method of inducing a crack in a thin film crystalline layer, the method comprising: providing a layered material comprising a first layer and a second layer, wherein the second layer is disposed on the first layer, wherein the second layer is crystalline and is under tensile stress (this second layer also being termed a thin film crystalline layer); and applying a potential difference between an electrode and the layered material to induce a crack extending from a location on the second layer located closest to the electrode. Also provided are layered materials, electronic devices, and systems related to the method.

### FIELD OF INVENTION

The present application relates to electrically inducing cracks in a thin film and the application of films with cracks and methods for inducing cracks in films towards devices.

### BACKGROUND

Inducing cracks in thin films is of interest to a broad range of applications, including, but not limited to, microfluidic and nanofluidic devices, crack-assisted lithography, strain sensors, and templates for growing nanowires. It is therefore desirable to develop methods to induce cracks in thin films.

Current methods for inducing cracks in thin films include spontaneous cracking due to tensile stress imposed by the substrate or phase transitions in clamped thin films or changes of volume or dimensions of the underlying substrate or film (e.g. due to thermal expansion/contraction, due to electrostriction or piezoelectric effects, or application of tensile stress). While these methods are effective for inducing cracks, the location of the cracks and the timing of their formation by these methods cannot be controlled. Current methods for controlling cracks in thin films, where deterministic positioning of the cracks is required, involves the creation of nucleation sites for the crack in the thin film. These nucleation sites are often in the form of a mechanical defect such as a notch, indent, or other stress raiser.

These methods have the disadvantage that in devices with multiple nucleation sites the timing of individual crack formation is not controlled. Furthermore, in the context of electronic devices, it would be advantageous if the timing and location of the cracks could be controlled post-fabrication.

There is a need for a method to induce cracks in thin films that would allow the location, timing, and direction of the induced crack to be controlled.

### BRIEF DESCRIPTION OF THE FIGURES

FIG. 1 illustrates schematically an example of the proposed system and method for electrically inducing cracks.

FIG. 2 shows atomic force microscopy (AFM) topography of an example of the layered material described herein after applying 10 V for 10 seconds to the tip positioned at the centre of the image. Application of voltage generates a topographical defect visible as a raised (bright) area in the centre of the image, and a channel crack running from top left to bottom right of the image. The opening of the crack can be seen as a thin dark line running through the centre of the crack and a small depression in the surface profile along the white line in (a) shown in (b). A schematic of the crack is shown in panel c. The material and the methods of testing related to this and all subsequent Figures are described in more detail in the Examples below.

FIG. 3 shows surface topography of an example of the layered material described herein, more specifically a 26 nm thick ITO film on a YSZ substrate imaged using AFM after writing a pattern of squares by applying different voltages while scanning the tip over a 100 nm square area, as shown on the right. Voltages of either polarity with magnitude of 4.5 V or above are sufficient to produce a defect (visible as a bright feature with a large change of topography) and corresponding crack(s) running along [110] or [−110] directions (visible as straight line features with a height of <1 nm above the film surface). Cracks terminate when they encounter another crack or defect.

FIG. 4 shows images of cracks written by rastering the AFM tip along the layered material from FIG. 2 along <110> directions while applying −5 to −7 V. Areas where the voltage was applied appear as bright rectangles corresponding to the areas of the highest topography. In most cases, induced cracks run parallel to the rastering direction. Image edges are approximately aligned with the crystallographic <100> directions.

FIG. 5 shows bias-induced tunnel cracks in another example of the layered material, which includes a HZO (Hf_{0.5}Zr_{0.5}O₂) (9 nm)/ITO (20 nm)//YSZ heterostructure. (a) Images of cracks written by rastering the AFM tip along <110> directions while applying −6 to −9V. (b) a zoomed-in region where two cracks meet, and there is no thin dark line running through the centre of the crack. (c) Schematic of the tunnel cracks in this heterostructure.

FIG. 6 shows an example where cracks were induced by application of 6.5 V to a circular Pt top electrode (diameter =50 μm) on a layered material having a HZO (13.5 nm)/ITO (18 nm) heterostructure on (100)-oriented YSZ. (a) shows the induced cracks on the HZO surface, and (b) shows the top right region of the Pt electrode where the cracks formed.

FIG. 7 shows examples of topography (a) 100 nm film and (b-d) 24 nm film of a layered material comprising ITO on (110) YSZ. (b) As grown; (c&d) after application of 4V with an AFM tip near the centre of the image in (c).

FIG. 8 shows examples of topography of (a-c) a 100 nm film and (d-f) a 24 nm film of a layered material comprising ITO on (111) YSZ. (a-d) as grown films. (e) after application of 5 V to points 1 and 2, (f) after repeated AFM scans following application of voltage to points 1 and 2 in (e).

FIG. 9 shows examples of a proposed In₂O₃/ITO/In₂O₃ trilayer for enhancing the crack opening in ITO layer. (a) Channel crack in structure with first layer comprising YSZ and second layer comprising In₂O₃/ITO/In₂O₃ trilayer. (b) Tunnel crack in structure with first layer comprising YSZ, second layer comprising In₂O₃/ITO/In₂O₃ trilayer and third layer comprising HZO.

FIG. 10 shows a schematic diagram of an example of a two-terminal “fuse” device.

FIG. 11 shows a schematic diagram of an example of a three-terminal “PROM” (programmable read only memory) device.

FIG. 12 shows schematic diagrams of an example of (a) three-and (b) four-terminal crack-based piezotransistor devices.

### SUMMARY OF THE INVENTION

In a first aspect, there is provided a method of inducing a crack in a thin film crystalline layer, the method comprising:
a. providing a layered material comprising a first layer and a second layer, wherein the second layer is disposed on the first layer, wherein the second layer is crystalline and is under tensile stress (this second layer also being termed a thin film crystalline layer),
b. applying a potential difference between an electrode and the layered material to induce a crack extending from a location on the second layer located closest to the electrode.

In a second aspect, there is provided a layered material comprising a first layer and a second layer, wherein the second layer is disposed on the first layer, wherein the second layer is crystalline (this second layer also being termed a thin film crystalline layer), wherein the second layer has a crack therein, the crack having been induced by applying a potential difference at a location on the layered material while the second layer is under tensile stress.

In a third aspect, there is provided a system for inducing cracks in a thin film crystalline layer, the system comprising:
a. a layered material comprising a first layer and a second layer, wherein the second layer is disposed on the first layer, wherein the second layer is crystalline and is under tensile stress (this second layer also being termed a thin film crystalline layer);
b. an electrode, to allow a potential difference to be applied at a location on the layered material to induce a crack in the second layer extending from a location on the second layer located closest to the location of the applied potential difference on the layered material.

In a fourth aspect, there is provided an electronic device comprising the layered material according to the second aspect or a system according to the third aspect. The electronic device may comprise at least one electrode disposed across the layered material, and the layered material is a component of an electronic circuit, wherein when the induced crack is formed it reduces or prevents the flow of electricity along the component of the electronic device that the layered material forms part of. In the present context, “reduces the flow of electricity along the component of the electronic device” indicates a reduction compared to an equivalent device lacking the induced crack. The electronic device may be selected from a two-terminal fuse, a three-terminal PROM, a three-or four-terminal crack-based piezotransistor, a pressure/touch sensor, and a nanofluidic channel.

The present inventors have found a method for deterministically inducing individual channel cracks and tunnel cracks in thin films in specific locations by application of electrical voltage or current pulses. The present inventors have also found that the cracks can be induced along a specific direction by moving the electrode along that desired direction during the application of the electrical voltage or current pulses. In comparison to existing methods of forming cracks, the ability of the present invention to control the location, orientation and timing of the individual crack formation means that complex crack patterns can be produced. Cracks in thin films and the formation of cracks in thin films via this method has applications in electronic devices including, but not limited to, a two-terminal fuse, a three-terminal “PROM” (programmable read only memory), a three-and four-terminal crack-based piezotransistor, pressure/touch sensors, strain sensors, nanofluidic channels, microfluidic devices, nanolithography, crack-assisted lithography, and templates for nanowire growth. Compared to existing methods of forming cracks, the present invention allows formation of individual and multiple cracks to be initiated post-fabrication of the device.

Existing methods of inducing cracks may exploit piezoelectric substrates to stress the overlying film causing it to crack. Application of a potential difference across a piezoelectric material may cause expansion of the piezoelectric material which may induce a crack in an overlying film. However, the location of cracks generated by this method is not well controlled. The subject matter of the present disclosure differs from these previous methods in that the present disclosure may not require the use of piezoelectric materials to induce cracks. The present disclosure induces cracks in a thin film crystalline layer by application of a potential difference across a layered material where the thin film crystalline layer is disposed on a first layer and is under tensile stress. According to the present disclosure, the thin film crystalline layer is under tensile stress and may be under stress prior to the application of a potential difference to induce a crack therein. In an example of the present disclosure, application of a potential difference across a layered material which is under tensile stress causes the tensile stress in the layered material to be released through crack formation. This differs to cracks formed as a result of the expansion of a piezoelectric material. Piezoelectric materials may be used in combination with the method and materials described herein.

### DETAILED DESCRIPTION

The present disclosure provides the aspects mentioned above. Optional and preferred features of the various aspects are described below. Unless otherwise stated, any optional or preferred feature may be combined with any other optional or preferred feature, and with any of the aspects of the invention mentioned herein.

It is noted that when discussing the method, product, or the systems of the present disclosure, each of these discussions can be considered applicable to other examples whether or not they are explicitly discussed in the context of that example. Thus, for example, in discussing a component related to the method, such disclosure is also relevant to and directly supported in context of the product, and vice versa. It is also noted that when discussing materials under tensile stress, each of these discussions can be considered applicable to materials under tensile strain, and vice versa.

The present disclosure provides, in a first aspect, a method of inducing a crack in a thin film crystalline layer, the method comprising:
a. providing a layered material comprising a first layer and a second layer, wherein the second layer is disposed on the first layer, wherein the second layer is crystalline and is under tensile stress (this second layer also being termed a thin film crystalline layer),
b. applying a potential difference between an electrode and the layered material to induce a crack extending from a location on the second layer located closest to the electrode.

### First Layer

The first layer, also being termed the substrate, may comprise an amorphous material or a crystalline material, where crystalline material includes single crystalline and polycrystalline.

The substrate preferably comprises a single crystalline material. The substrate may comprise a polycrystalline material.

The substrate may comprise an electrically conducting or non-electrically conducting material. Electrically conducting materials can be defined as a conductor, a semiconductor, and a superconductor. The substrate may comprise an insulator. An electrically conducting material can be defined as a material which has a conductivity of at least 1×10⁻⁶ S/m at 20° C. A non-electrically conducting material can be defined as a material which has a conductivity of less than 1×10⁻⁶ S/m at 20° C. Non-electrically conducting materials can be termed insulators.

The substrate may comprise a material selected from an inorganic material or a polymeric material. The substrate may comprise an inorganic material which comprises a ceramic. The substrate may comprise a metal or metalloid. The substrate may comprise an oxide. The substrate may comprise a metal oxide. The substrate may comprise a metal oxide, wherein the metal is a transition metal. The substrate may comprise a doped metal oxide. The substrate may comprise a silicon comprising material. The substrate may comprise a material that is a piezoelectric, a pyroelectric, a ferroelectric or a relaxor. The substrate may comprise no piezoelectric materials.

The substrate may comprise a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF. The substrate may comprise solid solutions of the aforementioned materials. The substrate may comprise the aforementioned materials in doped, substituted or oxygen deficient form. The substrate preferably comprises YSZ, SrTiO₃ or Si.

The substrate may comprise a crystalline material with a defined crystallographic orientation. The substrate may comprise a (100), (110) or (111)-oriented crystal, which may comprise a material mentioned herein, e.g. YSZ.

The substrate may have, disposed thereon, a buffer layer. Buffer layers may act as intermediate layers between the substrate and the epitaxially grown thin film. The buffer layers can control the effects of epitaxy such as mismatch of lattice parameters, coefficient of thermal expansion, interdiffusion of elements, and promote crystallisation of the film. The buffer layers may comprise an oxide or a nitride. The buffer layers may comprise a metal. The buffer layers may comprise a metal oxide or metal nitride. The buffer layer may comprise a multilayer, i.e. a stack of buffer layers comprised of different materials. The buffer layers may comprise a graded layer, i.e. a material with a gradient of compositions. The buffer layer may comprise any of the aforementioned substrate materials deposited on any other of the aforementioned substrate materials. The buffer layer may comprise any of the aforementioned substrate materials deposited homoepitaxially on the substrate, or heteroepitaxially on any of the aforementioned substrate materials. The buffer layer may comprise n-type of p-type semiconductor. The buffer layers may comprise CeO₂, SrRuO₃, LaNiO₃, SrO, BaSnO₃, BiFeO₃, ZnO, MoO₃, WO₃, SiO₂, Si, n-type Si, p-type Si, graphene, and Nb²O⁵.

The first layer may comprise a transparent, translucent, or opaque material.

The thickness of the first layer may be greater than the second layer. Preferably, the thickness of the first layer may be greater than the second layer. The first layer may be about 80 nm or more, optionally from about 80 nm to about 5 cm, optionally from about 80 nm to about 1 cm, optionally from about 80 nm to about 1 mm. The first layer may be no thinner than about 100 nm, optionally no thinner than about 200 nm, optionally no thinner than 500 nm. The thickness of the first layer, or any layer mentioned herein, may be measured using a suitable device, such as a scanning tunnelling microscope or an atomic force microscope or ellipsometry.

### Second Layer

The second layer, also being termed a thin film crystalline layer, is disposed on the first layer. The second layer is a crystalline material, where the crystalline material may comprise a single crystalline or polycrystalline material. The second layer may comprise an electrically conducting or non-conducting material. Electrically conducting materials can be defined as a conductor, a semiconductor, and a superconductor. The second layer may comprise an n-type or a p-type semiconductor. The second layer may comprise a wide band gap semiconductor. The second layer may comprise an n-type or a p-type wide band gap semiconductor. The second layer may comprise a direct band gap or indirect band gap semiconductor. The second layer may comprise an n-type or a p-type direct band gap semiconductor. The second layer may comprise a conductive thin film. The second layer may comprise no piezoelectric materials.

The second layer may comprise a transparent, translucent, or opaque material. The second layer may comprise a conductive transparent material. The second layer may comprise a metal. The second layer may comprise an oxide or a nitride. The second layer may comprise a metal oxide or metal nitride. The second layer may be doped. The second layer may comprise a doped metal oxide, where the dopant is an n-type or p-type donor. The second layer may comprise a doped metal nitride, where the dopant is an n-type or p-type donor. The second layer may comprise a doped material, where the dopant is an n-type or p-type donor.

The second layer may comprise a material selected from ITO (indium tin oxide), In₂O₃, VO₂, V₂O₃, Fe₂O₃, Fe₃O₄, MoO₃, MoO₂, ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN. The second layer preferably comprises ITO.

The second layer may comprise an electrically conducting material selected from ITO, In₂O₃, VO₂, V₂O₃, Fe₃O₄, MoO₃, MoO₂, ZnO, SnO₂, TiO₂, aluminium-doped ZnO (AZO), indium-doped cadmium oxide, gallium-doped zinc oxide, fluorine-doped tin oxide (FTO), indium-doped zinc oxide, graphite, graphene, graphene oxide, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN. These electrically conducting materials may be doped with one or more metal ions to increase conductivity.

The second layer may comprise an insulating material selected from Fe₂O₃, Al₂O₃, LaAlO₃ and SrTiO₃.

The second layer may comprise a bilayer or a tri-layer or a multilayer. The second layer may comprise a bilayer comprising an electrically conducting material and an insulator. The second layer may comprise a bilayer comprising an electrically conducting material and an insulator, wherein the insulator is disposed between the first layer and the electrically conducting material of the bi-layer. The second layer may comprise a bilayer comprising an electrically conducting material and an insulator, and the electrically conducting material is disposed between the first layer and the insulator of the bi-layer. The second layer may comprise a tri-layer which may comprise an insulator and an electrically conducting material. The second layer may comprise a tri-layer comprising a layer of electrically conducting material and two layers of insulators, wherein the electrically conducting material is disposed between the two insulating layers. The second layer may comprise a multilayer which may comprise a stack of conducting materials, insulating materials or a combination of conducting and insulating materials. The second layer may comprise a bilayer, tri-layer or multilayer that includes a material with a compositional gradient.

The second layer may comprise a bilayer, tri-layer or multilayer. The bi-layer, tri-layer or multilayer may comprise electrically conducting materials and insulators. The electrically conducting materials of the bi-layer, tri-layer or multilayer may comprise a material selected from ITO, ZnO, SnO₂, TiO₂, aluminium-doped ZnO (AZO), indium-doped cadmium oxide, gallium-doped zinc oxide, fluorine-doped tin oxide (FTO), indium-doped zinc oxide, graphene, BaSnO₃, Nb—SrTiO₃, SrRuO₃, LaNiO₃, lanthanum strontium manganite (LSMO), WO₃, GaN, Zn₃N₂, CaZn₂N₂, Cu₃N, TiN, ZrN, HfN, NbN, VN, and TaN.

The second layer may comprise a superlattice which comprises a repeating stack of bilayers, tri-layers or multilayers or different materials. The second layer may comprise a bilayer, tri-layer or multilayer where one or more of the components is a superlattice. The second layer may comprise a solid solution of two or more different materials. The second layer may comprise a bilayer, tri-layer or multilayer where one or more of the components is a solid solution.

The second layer may comprise an insulator. The second layer may comprise an insulator which when deposited on the first layer leads to the formation of a conducting interface. The second layer may comprise an insulator deposited on a conducting or semiconducting first layer. The second layer may comprise an insulator deposited on an insulating first layer where the first layer becomes conducting upon photoexcitation.

The second layer may have a thickness below a critical thickness for spontaneous cracking, herein defined as the critical thickness. The second layer may have a thickness above the critical thickness but below the thickness for full stress relaxation due to cracking or dislocation formation. The second layer preferably has a thickness below the critical thickness. The second layer may have a thickness of no greater than 500 nm, optionally no greater than 200 nm, optionally no greater than 100 nm, optionally no greater than 90 nm, optionally no greater than 80 nm, optionally no greater than 70 nm, optionally no greater than 50 nm. The second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The second layer may have been epitaxially grown on the first layer. The epitaxial growth may be heteroepitaxial. The second layer may also be termed an epitaxially grown thin film. The second layer may have been epitaxially grown on the first layer which has a buffer layer disposed thereon. The second layer may have been epitaxially grown on the first layer, whereby the crystallographic orientation of the second layer is determined by the crystallographic orientation of the first layer. There are various methods of growing thin films on substrates. The second layer may have been grown on the first layer by methods including, but not limited to, liquid phase epitaxy (LPE), chemical vapour deposition (CVD), physical vapour deposition (PVD), molecular beam epitaxy (MBE), chemical beam epitaxy (CBE), electron beam evaporation, atomic layer epitaxy (ALE) also known as atomic layer deposition (ALD), sputtering, magnetron sputtering, pulsed DC magnetron sputtering, radiofrequency magnetron sputtering, off-axis radiofrequency magnetron sputtering, ion beam sputtering, pulsed laser deposition (PLD), laser ablation, and thermal laser evaporation.

The thin films can preferably be grown using magnetron sputtering, more preferably be grown using off axis radio-frequency magnetron sputtering. During epitaxial growth, the temperature, pressure, time, and atmosphere at which deposition and growth occurs can be varied. The atmosphere during epitaxial growth may be an Ar/O₂ atmosphere where the ratio of Ar:O₂ may be varied. The atmosphere during epitaxial growth may be an Ar/N₂ atmosphere where the ratio of Ar:N₂ may be varied. The atmosphere during epitaxial growth may be an Ar atmosphere.

When the method of epitaxial thin film growth is sputtering, the temperature at which deposition of epitaxial growth occurs may be from about 20° C. to about 1500° C., optionally from about 100° C. to about 1500° C., optionally from about 200° C. to about 1500° C., optionally from about 200° C. to about 1000° C., optionally about from about 300° C. to about 900° C. optionally from about 400° C. to about 800° C., optionally about 700° C. The temperature at which epitaxial growth occurs in this context is defined as the temperature of the substrate.

When the method of epitaxial thin film growth is sputtering, the pressure at which deposition of epitaxial growth occurs may be from about 0.005 Torr to about 760 Torr, optionally from about 0.005 Torr to about 1 Torr, optionally from about 0.01 Torr to about 0.5 Torr, optionally from about 0.05 Torr to about 0.5 Torr, optionally from about 0.05 Torr to about 0.25 Torr, optionally about 0.1 Torr.

The second layer is disposed on the first layer and is under tensile stress. The tensile stress in the second layer may be due to a difference in bulk lattice parameter between the first layer and the second layer. The tensile stress in the second layer may be due to a difference in bulk lattice parameter between the first layer and the second layer, at the interface between the first layer and the second layer. The tensile stress in the second layer may be due to the second layer having a bigger bulk lattice parameter than the first layer. The tensile stress in the second layer may be due to the second layer having a smaller bulk lattice parameter than the first layer.

The bulk lattice parameter of a material can be defined as the lattice parameter of a single crystal of the material (i.e., the lattice parameter of the material in single crystal form when it is not bound to another material). In the case of an epitaxially grown thin films, the lattice parameter of the epitaxially grown thin film at the interface between the substrate and the thin film may be different from the bulk lattice parameter of the material for the epitaxially grown thin film. This difference in lattice parameter may result in tensile stress in the epitaxially grown thin film.

The lattice parameters may be defined in the x, y, and z directions, where the z direction is defined as being the direction across the shortest dimension of the layers in the layered material, and the x and y directions define the plane of the layers in the layered material. The tensile stress in the second layer may be due to a difference in the x bulk lattice parameters of the first layer and the second layer. The tensile stress in the second layer may be due to a difference in the y bulk lattice parameters of the first layer and the second layer. The tensile stress in the second layer may be due to a difference in the x and y bulk lattice parameters between the first layer and the second layer. The tensile stress in the second layer may be due to the bulk lattice parameters in the x and y direction of the first layer being smaller than the bulk lattice parameters in the x and y direction of the second layer. Preferably, the tensile strain in the second layer may be due to the bulk lattice parameters in the x and y direction of the first layer being bigger than the bulk lattice parameters in the x and y direction of the second layer. The tensile stress in the second layer may be due to any of the x, y and z bulk lattice parameters in the first layer being different to any of the x, y and z bulk lattice parameters in the second layer.

The tensile stress in the second layer may be due to a difference in the coefficients of thermal expansion (CTE) between the first layer and the second layer. The CTE describes the how the size of a material changes with temperature. The tensile stress in the second layer may occur upon cooling of the layered material after film deposition at an elevated temperature, where there is a difference in the CTE between the first and the second layer. The tensile stress in the second layer may be due to intrinsic or growth stresses.

The stress and strain energy in thin films generally increases with increasing thin film thickness. At the critical thickness, the stress and strain in the thin film (second layer) is relaxed through dislocation formation, surface roughening, cracking, or a combination thereof. For films below a certain thickness, the strain (or partial strain) can be sustained without relaxation. Often, a larger difference in bulk lattice parameter or larger difference in CTE will result in a smaller critical thickness at which relaxation of stress and strain will occur. According to the present disclosure, the thickness of the second layer is preferably below the critical thickness for spontaneous cracking. If the thickness is not below the critical thickness for spontaneous cracking then the thickness is below the value required to completely relax the tensile stress by cracking or other mechanisms such as formation of dislocations or surface roughening. The critical thickness value will depend on factors including, but not limited to, the composition of the layered material, the method of epitaxial growth during formation of the thin film, the conditions of epitaxial growth, the thickness of the layers in the layered material, the magnitude of the difference in bulk lattice parameters of the first layer and the second layer, the magnitude of the difference in the CTE of the first layer and the second layer, and the post-deposition treatment of the layers such as the rate at which they are cooled from the deposition temperature.

The tensile strain of the thin film can be determined by methods including, but not limited to, X-ray diffraction, Raman spectroscopy, convergent beam electron diffraction, high-resolution transmission electron microscopy. According to the present disclosure, the magnitude of the tensile strain in the thin film may be lower than that which results in complete strain relaxation, and preferably lower than that which results in spontaneous cracking of the thin film. X-ray diffraction, scanning electron microscopy (SEM), transmission electron microscopy (TEM), scanning tunnelling microscopy (STM) and atomic force microscopy (AFM) can be employed to determine whether the thin film has undergone relaxation.

### Third Layer

The layered material may additionally comprise a third layer which is disposed on the second layer. The layered material may additionally comprise a third layer which is disposed on the second layer, wherein the induced crack in the second layer, formed by application of the potential difference between the electrode and the second layer, does not extend into the third layer or extends only partially into the third layer, i.e. a tunnel crack is formed.

The third layer may comprise an amorphous material or a crystalline material, where crystalline material includes crystalline and polycrystalline. The third layer preferably comprises a single crystalline material. The third layer may be a single crystal of a crystalline material. The third layer may comprise a polycrystalline material. The third layer may comprise an electrically conducting or non-electrically conducting material, preferably a non-electrically conducting material. Electrically conducting materials can be defined as a conductor, a semiconductor, and a superconductor. The third layer may comprise an insulator.

The third layer may comprise a material selected from an inorganic material or a polymeric material. The third layer may comprise an inorganic material which comprises a ceramic. The third layer may comprise a metal or metalloid. The third layer may comprise an oxide. The third layer may comprise a metal oxide. The third layer may comprise a metal oxide, wherein the metal is a transition metal. The third may comprise a doped metal oxide. The third layer may comprise a silicon comprising material. The third layer may be the same as the first layer or buffer layer. The third layer may be different to the first layer or buffer layer.

The third layer may comprise a material selected from hafnia-zirconia HfₓZr₁₋ₓO₂ (HZO), HfO₂, ZrO₂, and YSZ.

The third layer may have been epitaxially grown on the second layer. The epitaxial growth may be heteroepitaxial. The third layer may have been epitaxially grown on the second layer, whereby the crystallographic orientation of the third layer is determined by the crystallographic orientation of the second layer. There are various methods of growing thin films on substrates. The third layer may have been grown on the second layer by methods including, but not limited to, liquid phase epitaxy (LPE), chemical vapour deposition (CVD), physical vapour deposition (PVD), molecular beam epitaxy (MBE), chemical beam epitaxy (CBE), electron beam evaporation, atomic layer epitaxy (ALE), sputtering, magnetron sputtering, pulsed DC magnetron sputtering, radiofrequency magnetron sputtering, off-axis radiofrequency magnetron sputtering, ion beam sputtering, pulsed laser deposition (PLD), laser ablation, and thermal laser evaporation.

The thin films can preferably be grown using magnetron sputtering, more preferably be grown using off axis radio-frequency magnetron sputtering. During epitaxial growth, the temperature, pressure, time, and atmosphere at which deposition and growth occurs can be varied. The atmosphere during epitaxial growth may be an Ar/O₂ atmosphere where the ratio of Ar:O₂ may be varied. The atmosphere during epitaxial growth may be an Ar/N₂ atmosphere where the ratio of Ar:N₂ may be varied. The atmosphere during epitaxial growth may be an Ar atmosphere.

When the method of epitaxial thin film growth is sputtering, the temperature at which deposition of epitaxial growth occurs may be from about 20° C. to about 1500° C., optionally from about 100° C. to about 1500° C., optionally from about 200° C. to about 1500° C., optionally from about 200° C. to about 1000° C., optionally about from about 300° C. to about 900° C. optionally from about 400° C. to about 800° C., optionally about 700° C. The temperature at which epitaxial growth occurs in this context is defined as the temperature of the substrate.

When the method of epitaxial thin film growth is sputtering, the pressure at which deposition of epitaxial growth occurs may be from about 0.005 Torr to about 760 Torr, optionally from about 0.005 Torr to about 1 Torr, optionally from about 0.01 Torr to about 0.5 Torr, optionally from about 0.05 Torr to about 0.5 Torr, optionally from about 0.05 Torr to about 0.25 Torr, optionally about 0.1 Torr.

The third layer may have a thickness of from about 1-100 nm, optionally from about 1-90 nm, optionally from about 1-80 nm, optionally from about 1-70 nm, optionally from about 1-60 nm, optionally from about 1-50 nm, optionally from about 2-40 nm, optionally from about 3-30 nm, optionally from about 4-25 nm, optionally from about 5-20 nm, optionally from about 5-15 nm, optionally about 10 nm.

### Cracks

The cracks can be induced in the second layer of the layered material by applying a potential difference between an electrode and the layered material. The cracks can be induced in the second layer of the layered material by applying a potential difference between an electrode and the first layer of the layered material. The cracks can be induced in the second layer of the layered material by applying a potential difference between an electrode and the second layer. The cracks in the second layer of the layered material extend from a location on the second layer located closest to the electrode.

The cracks may have a straight or curved geometry. The cracks may be straight line cracks. The induced cracks may have a substantially straight line geometry over the whole length of the induced crack. The cracks may form along crystallographic planes. The cracks may typically form along the crystallographic planes of the second layer of the layered material, for example, but not limited to, the {100}, {110} and {111} planes.

A plurality of cracks may be induced in the second layer of the layered material. A plurality of cracks may be induced electrically in the second layer of the layered material. A plurality of cracks may be induced in the second layer of the layered material either simultaneously or consecutively. The induced crack in the second layer may propagate until it encounters another extended defect, e.g. another crack, which itself may have been produced (or induced) by the method described herein. Complex patterns of induced cracks in the second layer of the layered material can be formed. A plurality of induced cracks in the second layer of the layered material can form a pattern of cracks, optionally a complex pattern of cracks. A complex pattern of cracks may be a pattern that involves three or more cracks and, optionally, the cracks intersect and/or at least two of which are at different angles to one another.

### Layered material

The layered material comprises the first layer and the second layer, wherein the second layer is disposed on the first layer. The layered material comprises the first layer and the second layer, wherein the second layer is disposed on the first layer, wherein the second layer is crystalline. The layered material comprises the first layer and the second layer, wherein the second layer is disposed on the first layer, wherein the second layer is crystalline and may have a thickness below a critical thickness for spontaneous cracking. The layered material in which the second layer is under tensile stress may not have a crack in the second layer, or may not have a crack in the second layer induced by the method of the first aspect. Depending on the context, the layered material referred to herein is the layered material in which the second layer is under tensile stress and has not had a crack induced therein using the method described herein, unless specified. The layered material may have a pre-existing crack or plurality of pre-existing cracks induced in it using methods other than the method described in the first aspect. A layered material in which a crack has been induced in the second layer by the method described herein may be termed a “cracked layered material”. The layered material optionally comprises the third layer disposed on the second layer. The optional and preferred features of the first, second and third layers described previously may be incorporated into the layered material, and combined with any other optional or preferred feature, and with any of the aspects of the invention mentioned herein.

The layered material may comprise the first layer comprising a non-electrically conducting material and the second layer comprising an electrically conducting material. The layered material may comprise the first layer comprising a non-electrically conducting material, the second layer comprising an electrically conducting material, and the third layer comprising a non-electrically conducting material.

The layered material may comprise the first layer comprising a non-electrically conducting material and the second layer comprising an electrically conducting material, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising a non-electrically conducting material and the second layer comprising an electrically conducting material, and the second layer is of a thickness of about from 5-50 nm.

The layered material may comprise the first layer comprising a non-electrically conducting material, the second layer comprising an electrically conducting material, and the third layer comprising a non-electrically conducting material, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising a non-electrically conducting material, the second layer comprising an electrically conducting material, and the third layer comprising a non-electrically conducting material, and the second layer is of a thickness of about from 5-50 nm.

The layered material may comprise the first layer comprising an electrically conducting material, and the second layer comprising a non-electrically conducting material, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising an electrically conducting material, and the second layer comprising a non-electrically conducting material, and the second layer is of a thickness of about from 5-50 nm.

The layered material may comprise the first layer comprising a non-electrically conducting material, and the second layer comprising a non-electrically conducting material, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising a non-electrically conducting material, and the second layer comprising a non-electrically conducting material, and the second layer is of a thickness of about from 5-50 nm.

The layered material may comprise the first layer comprising an inorganic material or a polymeric material, and the second layer comprising an oxide or a nitride. The layered material may comprise the first layer comprising an inorganic material or a polymeric material, the second layer comprising an oxide or a nitride, and the third layer comprising an inorganic material or a polymeric material.

The layered material may comprise the first layer comprising an inorganic material or a polymeric material, and the second layer comprising an oxide or a nitride, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising an inorganic material or a polymeric material, and the second layer comprising an oxide or a nitride, and the second layer is of a thickness of from about 5-50 nm.

The layered material may comprise the first layer comprising an inorganic material or a polymeric material, the second layer comprising an oxide or a nitride, and the third layer comprising an inorganic material or a polymeric material, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising an inorganic material or a polymeric material, the second layer comprising an oxide or a nitride, and the third layer comprising an inorganic material or a polymeric material, and the second layer is of a thickness of from about 5-50 nm.

The layered material may comprise the first layer comprising an inorganic material or a polymeric material, and the second layer comprising a metal oxide or a metal nitride. The layered material may comprise the first layer comprising an inorganic material or a polymeric material, the second layer comprising a metal oxide or a metal nitride, and the third layer comprising an inorganic material or a polymeric material.

The layered material may comprise the first layer comprising an inorganic material or a polymeric material, and the second layer comprising a metal oxide or a metal nitride, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising an inorganic material or a polymeric material, and the second layer comprising a metal oxide or a metal nitride, and the second layer is of a thickness of from about 5-50 nm.

The layered material may comprise the first layer comprising an inorganic material or a polymeric material, the second layer comprising a metal oxide or a metal nitride, and the third layer comprising an inorganic material or a polymeric material, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm.

The layered material may comprise the first layer comprising an inorganic material or a polymeric material, the second layer comprising a metal oxide or a metal nitride, and the third layer comprising an inorganic material or a polymeric material, and the second layer is of a thickness of from about 5-50 nm.

The layered material may comprise the first layer comprising a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF, and the second layer comprising a material selected from ITO, In₂O₃, VO₂, V₂O₃, Fe₂O₃, Fe₃O₄, MoO₃, MoO₂ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN.

The layered material may comprise the first layer comprising a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF, and the second layer comprising a material selected from ITO, In₂O₃, VO₂, V₂O₃, Fe₂O₃, Fe₃O₄, MoO₃, MoO₂ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN, and the second layer is of a thickness from about 5-50 nm.

The layered material may comprise the first layer comprising a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF, the second layer comprising a material selected from ITO, In₂O₃, VO₂, V₂O₃, Fe₂O₃, Fe₃O₄, MoO₃, MoO₂ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN, and the third layer comprising and inorganic material or a polymeric material.

The layered material may comprise the first layer comprising a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF, the second layer comprising a material selected from ITO, In₂O₃, VO₂,

V₂O₃, Fe₂O₃, Fe₃O₄, MoO₃, MoO₂ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN, and the third layer comprising and inorganic material or a polymeric material, and the second layer is of a thickness from about 5-50 nm.

The layered material may comprise the first layer comprising YSZ and the second layer comprising ITO. The layered material may comprise the first layer comprising YSZ, the second layer comprising ITO, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm. The layered material may comprise the first layer comprising YSZ, the second layer comprising ITO, and the second layer is of a thickness of about 5-50 nm.

The layered material may comprise the first layer comprising YSZ, the second layer comprising ITO, and the third layer comprising HZO. The layered material may comprise the first layer comprising YSZ, the second layer comprising ITO, and the third layer comprising HZO, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm. The layered material may comprise the first layer comprising YSZ, the second layer comprising ITO, and the third layer comprising HZO, and the second layer is of a thickness of about 5-50 nm.

The layered material may comprise the first layer comprising SrTiO₃ and the second layer comprising LaAlO₃. The layered material may comprise the first layer comprising SrTiO₃, the second layer comprising LaAlO₃, and the second layer may have a thickness of no greater than 100 nm, optionally no greater than 90 nm, optionally no greater than 80 nm, optionally no greater than 70 nm, optionally no greater than 50 nm, optionally no greater than 20 nm, optionally the second layer may have a thickness of from about 1-100 nm, optionally from about 1-90 nm, optionally from about 1-80 nm, optionally from about 1-50 nm, optionally from about 3-20 nm, optionally from about 4-55 nm, optionally from about 5-50 nm, optionally from about 10-45 nm, optionally from about 10-40 nm, optionally from about 15-30 nm, optionally about 15 nm. The layered material may comprise the first layer comprising SrTiO₃, the second layer comprising LaAlO₃, and the second layer is of a thickness of about 5-25 nm.

The layered material may comprise the first layer comprising Si with a YSZ buffer and the second layer comprising ITO. The layered material may comprise the first layer comprising Si with a YSZ buffer, the second layer comprising ITO, and the buffer layer may have a thickness of no greater than 200 nm optionally no greater than 100 nm, optinonally no greater than 50 nm, optionally no greater than 25 nm, optionally no greater than 10 nm, and the second layer may have a thickness of no greater than 100 nm, optionally no greater than 90 nm, optionally no greater than 80 nm, optionally no greater than 70 nm, optionally no greater than 50 nm, optionally the second layer may have a thickness of from about 1-100 nm, optionally from about 1-90 nm, optionally from about 1-80 nm, optionally from about 2-70 nm, optionally from about 3-60 nm, optionally from about 4-55 nm, optionally from about 5-50 nm, optionally from about 10-45 nm, optionally from about 10-40 nm, optionally from about 15-30 nm, optionally about 25 nm. The layered material may comprise the first layer comprising Si, a buffer layer comprising YSZ, the second layer comprising ITO, the buffer layer is of a thickness of about 1-100 nm, and the second layer is of a thickness of about 5-50 nm.

### Method of Inducing Cracks

The present disclosure provides, in a first aspect, a method of inducing a crack in a thin film crystalline layer, the method comprising:
a. providing a layered material comprising a first layer and a second layer, wherein the second layer is disposed on the first layer, wherein the second layer is crystalline (this second layer also being termed a thin film crystalline layer),
b. applying a potential difference between an electrode and the layered material to induce a crack extending from a location on the second layer located closest to the electrode.

According to the present disclosure, application of a potential difference between the electrode and the layered material induces a crack extending from a location on the second layer closest to the electrode. Alternatively, application of a potential difference between the electrode and the second layer or between an electrode and the first layer induces a crack extending from a location on the second layer closest to the electrode. The potential difference may be applied to any layer of the layered material. The potential difference may be applied to the first layer, the second layer, or the third layer of the layered material. The potential difference may be applied across any layer of the layered material.

Unlike cracks induced by an expansion of a piezoelectric material, the cracks induced by the present disclosure may not be due to expansion of the layers in the layered material. The application of a potential difference to the layered material may not result in expansion of the layered material. The cracks in the layered material may form when the stress in the second layer is released due to application of a potential difference to the layered material.

The electrode may comprise a conductive material. The electrode may comprise a metal. The electrode may comprise a metal oxide. The electrode may comprise a doped metal oxide. The electrode may comprise a mixed metal oxide. The electrode may comprise a nitride. The electrode may comprise doped silicon. The electrode may comprise a material selected from Cu, C, Ag, Pt, Pd, Ru, Ir, Au, Al, Be, Bi, Cd, Co, Fe, Ga, Hg, In, Mo, Nb, Ni, Pb, Rh, Sn, Ta, Ti, W, steel, IrO₂, SrRuO₃, ITO, glassy carbon, YSZ, graphene, carbon nanotube, graphite, silicon, titanium nitride. The electrode may comprise a combination of any of these materials. The electrode may comprise and alloy of any of these materials. The electrode may comprise a multilayer of any of these materials.

The electrode may be a microscopic or a macroscopic electrode. The electrode may be a movable needle. The electrode may be the tip of a scanning probe microscope. The electrode may be an AFM tip. The electrode may be a thin film with a thickness below 1 μm. The electrode may be a thick film with a thickness above 1 μm. The electrode may be a circular top electrode. The electrode may be a square or rectangular top electrode. The electrode may have a complex or irregular shape. The electrode may have a complex shape comprising multiple interconnected stripes.

The thickness of the electrode can be defined as the shortest measurement across the electrode perpendicular to its interface with the layered material. The electrode may be a thick electrode with a thickness of from about 1-1000 μm, optionally from about 1-500 μm, optionally from about 1-100 μm, optionally from about 1-50 μm, optionally from about 1-20 μm, optionally from about 1-10 μm, optionally about 10 μm, optionally about 5 μm, optionally about 2 μm, optionally about 1 μm. The electrode may be a thin electrode with a thickness of from about 0.1-1000 nm, optionally from about 0.1-200 nm, optionally of from about 2-150 nm, optionally of from about 5-100 nm, optionally of from about 10-80 nm, optionally of from about 20-70 nm, optionally of from about 30-60 nm, optionally of about 50 nm, optionally of about 10 nm. The thickness of the electrode made be less than about 1000 nm, optionally less than about 100 nm, optionally less than about 1 nm, optionally less than about 0.01 nm.

The lateral dimension of the electrode is the smallest measurement across the electrode perpendicular to its thickness. The electrode may be a macroscopic electrode with a lateral dimension of from about 1-1000 μm, optionally from about 1-500 μm, optionally from about 10-500 μm, optionally from about 1-200 μm, optionally from about 5-200 μm, optionally from about 10-200 μm, optionally from about 1-100 μm, optionally from about 10-100 μm, optionally from about 1-10 μm, optionally about 100 μm, optionally about 50 μm, optionally about 10 μm, optionally about 5 μm, optionally about 2 μm, optionally about 1 μm. The electrode may be a microscopic electrode with a dimension of from about 1-1000 nm, optionally from about 1-200 nm, optionally of from about 2-150 nm, optionally of from about 5-100 nm, optionally of from about 10-80 nm, optionally of from about 20-70 nm, optionally of from about 30-60 nm, optionally of from about 2-50 nm, optionally of from about 2-10 nm, optionally of about 50 nm, optionally of about 10 nm, optionally of about 5 nm.

The electrode may be in the form of a needle with a sharp tip. The electrode may be an AFM tip. The tip dimension can be defined as the smallest radius of curvature of the tip surface. The tip may be macroscopic with a dimension of from about 1-1000 μm, optionally from about 1-500 μm, optionally from about 1-100 μm, optionally from about 1-50 μm, optionally from about 1-20 μm, optionally from about 1-10 μm, optionally about 10 μm, optionally about 5 μm, optionally about 2 μm, optionally about 1 μm. The tip may be microscopic with a dimension of from about 1-1000 nm, optionally from about 1-200 nm, optionally of from about 5-100 nm, optionally of from about 10-100 nm, optionally of from about 20-70 nm, optionally of from about 30-60 nm, optionally of about 20 nm, optionally of about 10 nm. The tip dimension may be less than 100 nm, optionally less than 50 nm, optionally less than 10 nm.

The electrode may be stationary relative to the layered material during application of the potential difference. The electrode may be moving relative to the layered material during application of the potential difference. The electrode may be fixed in place relative to the layered material.

There may be one electrode. There may be a plurality of electrodes.

The magnitude of the potential difference applied may be a constant voltage or variable voltage. The potential difference applied may be AC. The potential difference applied may be DC. The potential difference applied may result in a current pulse or current pulses. The potential difference applied may result in a constant DC current. The potential difference applied may have an arbitrary waveform. The potential difference applied may be positive or negative polarity. The potential difference applied, which may be DC, may have a magnitude of from about 1-100V, optionally of from about 1-50 V, optionally from about 1-40 V, optionally from about 1-30 V, optionally from about 2-20 V, optionally from about 3-10 V, optionally from about 4-8 V. The potential difference applied may be between 3-10 V of either polarity. The voltage required to nucleate the crack may depend on the sample, electrode/tip type, and conditions. The potential difference should induce a current in the second layer, e.g., the potential difference is applied across a continuous section of the second layer to induce a crack in that section.

The potential difference may be applied between the electrode and the first layer if the second layer is non-electrically conducting. The potential difference may be applied between the electrode and the buffer layer of the first layer if the second layer is non-electrically conducting. The potential difference may be applied between the electrode and a conducting interface between the first layer and the second layer in cases where the first layer and the second layer are non-electrically conducting.

The potential difference may be applied between the electrode and the second layer under optical illumination which causes excitation of photo-carriers in the second layer. The potential difference may be applied between the electrode and the first layer under optical illumination which causes excitation of photo-carriers in the first layer.

The potential difference may be applied for no greater than about 5 minutes, optionally no greater than 60 seconds, optionally no greater than about 30 seconds, optionally no greater than about 15 seconds, optionally no greater than about 10 seconds, optionally no greater than about 5 seconds, optionally no greater than 1 second, optionally no greater than 1 ms, optionally no greater than 0.1 ms, optionally no greater than 0.01 ms, optionally no greater than 1 ns, optionally no greater than 0.1 ns, optionally no greater than 0.01 ns. The potential difference applied may be applied for from about 0.01 ns to about 5 minutes, optionally from about 0.1 ns to about 60 seconds, optionally from about 1 ns to about 60 seconds, optionally from about 1 ms to about 60 seconds, optionally from about 0.1 seconds to about 30 seconds, optionally from about 0.1 seconds to about 15 seconds, optionally from about 1 second to about 10 seconds.

The potential difference may be applied from about 1-10 V for no greater than 10 seconds.

The electrode may be stationary (relative to the layered material) during application of the potential difference. The electrode may be moving (relative to the layered material) during the application of the potential difference. The electrode may be moving relative to the layered material during the application of the potential difference. The electrode may be fixed in place during the application of the potential difference. The electrode may be moving during the application of the potential difference, and the movement of the electrode controls the direction in which the induced crack forms. To induce a crack along a specific direction, the electrode may be moved along that direction during application of the potential difference. For example, in a specific embodiment, moving the electrode along the [110] crystallographic direction produces cracks predominantly along [110]. The propagation of the induced crack may stop when the crack encounters another extended defect, e.g. another crack.

### Channel Cracks

According to the present disclosure, a channel crack, also termed an open crack, may be induced in a thin film crystalline layer by providing a layered material comprising a first layer and a second layer, wherein the second layer is disposed on the first layer, wherein the second layer is crystalline, is under tensile stress, and applying a potential difference between an electrode and the layered material to induce a crack extending from a location on the second layer located closest to the electrode. The channel crack is a crack that is not covered, e.g. the channel crack is disposed in a layer that is an outermost layer of the layered material. The layered material may not have a third layer.

A channel crack may be induced in a thin film crystalline layer by providing a layered material comprising a first layer and a second layer, wherein the second layer is disposed on the first layer, wherein the second layer is crystalline, is under tensile stress, and applying a potential difference between an electrode and the second layer, or between an electrode and the first layer, to induce a crack extending from a location on the second layer located closest to the electrode.

### Tunnel Cracks

According to the present disclosure, a tunnel crack, may be induced in a thin film crystalline layer by providing a layered material comprising a first layer, a second layer, and a third layer, wherein the second layer is disposed on the first layer, and the third layer is disposed on the second layer, wherein the second layer is crystalline, is under tensile stress, and applying a potential difference between an electrode and the layered material, to induce a crack extending from a location on the second layer located closest to the electrode, and wherein the induced crack in the second layer does not extend into the third layer, i.e. a tunnel crack is formed. The tunnel crack in the second layer is capped or covered by the third layer, which does not have a crack therein.

A tunnel crack may be induced in a thin film crystalline layer by providing a layered material comprising a first layer, a second layer, and a third layer, wherein the second layer is disposed on the first layer, and the third layer is disposed on the second layer, wherein the second layer is crystalline, is under tensile stress, and applying a potential difference between an electrode and the second layer, or between an electrode and the first layer, to induce a crack extending from a location on the second layer located closest to the electrode, and wherein the induced crack in the second layer does not extend into the third layer, i.e. a tunnel crack is formed.

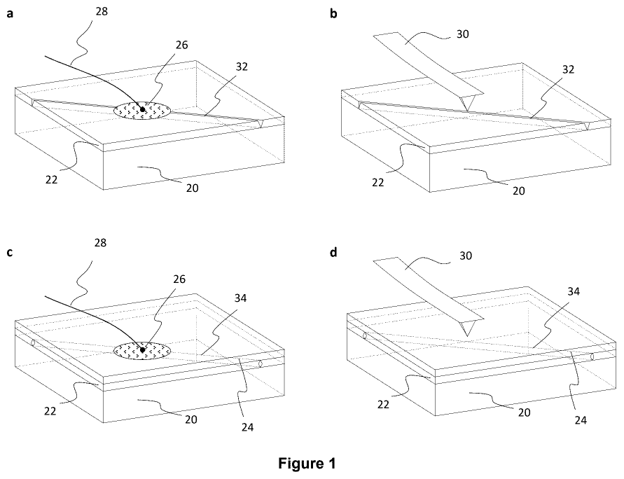

An example of the proposed system and method for electrically inducing cracks is depicted in FIG. 1. Indicated components include first layer 20, second layer 22, third layer 24, circular electrode 26, electrical connection 28 (e.g. wire) and conducting AFM tip 30. (a) Two-layer system with circular top electrode and a channel crack 32 in second layer induced by application of voltage between the electrode and the layered material (either between the electrode and the second layer or between the electrode and first layer). (b) Two-layer system with AFM tip electrode and a channel crack 32 in second layer induced by application of voltage between the electrode and the layered material (either between the electrode and the second layer or between the electrode and first layer). (c) Three-layer system with circular top electrode and a tunnel crack 34 in second layer induced by application of voltage between the electrode and the layered material (either between the electrode and the second layer or between the electrode and first layer). (d) Two-layer system with AFM tip electrode and a tunnel crack 34 in second layer induced by application of voltage between the electrode and the layered material (either between the electrode and the second layer or between the electrode and first layer).

### Cracked Layered Material

The present disclosure provides, in a second aspect, a layered material comprising a first layer and a second layer, wherein the second layer is disposed on the first layer, wherein the second layer is crystalline (this second layer also being termed a thin film crystalline layer), wherein the second layer has a crack therein, the crack having been induced by applying a potential difference at a location on layered material while the second layer is under tensile stress.

The cracked layered material may comprise a first layer and a second layer, wherein the second layer is disposed on the first layer, wherein the second layer is crystalline (this second layer also being termed a thin film crystalline layer), wherein the second layer has a crack therein, the crack having been induced by applying a potential difference at a location on the first layer or the second layer while the second layer is under tensile stress.

The cracked layered material is the layered material that has a crack induced therein in the second layer, wherein the crack in the second layer was induced according to the first aspect. All features described above in relation to the layered material, e.g. the materials of the first, second, and, if present, third layers, and thicknesses thereof, apply equally to the layered material with a crack therein and without a crack therein (i.e. before a crack has been induced).

The crack in the second layer may have been induced by application of a potential difference at a location on the second layer while the second layer is under tensile stress. The crack in the second layer may have been induced by application of a potential difference at a location on the second layer while the second layer is under tensile stress, where the induced crack extended from a location on the second layer closest to the electrode.

The tensile stress in the second layer may have been due to a difference in bulk lattice parameters between the first layer and the second layer. The tensile stress in the second layer may have been due to a difference in bulk lattice parameters between the first layer and the second layer, at the interface between the first layer and the second layer. The tensile stress in the second layer may have been due to the second layer having a bigger bulk lattice parameter than the first layer. The tensile stress in the second layer may have been due to the second layer having a smaller bulk lattice parameter than the first layer.

The tensile stress in the second layer may have been due to a difference in the coefficients of thermal expansion (CTE) between the first layer and the second layer. The CTE describes how the size of a material changes with temperature. The tensile stress in the second layer may have occurred upon cooling of the layered material after epitaxial film deposition at an elevated temperature, where there was a difference in the CTE between the first and the second layer. The tensile stress in the second layer may have been due to intrinsic or growth stresses.

The layered material may comprise the first layer, the second layer, and the third layer, wherein the second layer has a crack therein, the crack having been induced by applying a potential difference at a location on the layered material second layer while the second layer was under tensile stress, wherein the crack in the second layer does not extend into the third layer, i.e. a tunnel crack is formed.

The crack or cracks may have a straight or curved geometry. The crack or cracks may be straight line cracks. The induced crack(s) may have a substantially straight line geometry over the whole length of the induced crack. The induced crack(s) may have at least portion that is straight over a distance of at least 1 μm, optionally at least 3 μm, optionally at least 5 μm, optionally at least 10 μm, optionally at least 20 μm, optionally at least 30 μm. The induced crack(s) may have at least a portion that is straight over a distance of from 1 μm to 50 μm, optionally at 5 μm to 50 μm, optionally at 10 μm to 50 μm. The cracks may form along crystallographic planes. The cracks may typically form along at least one of the crystallographic planes of the second layer of the layered material, for example, but not limited to, the {100}, {110} and {111} planes.

A plurality of cracks may be induced in the second layer of the layered material. A plurality of cracks may be induced in the second layer of the layered material either simultaneously or consecutively. The induced crack in the second layer may propagate until it encounters another extended defect in the second layer, e.g. another crack, which may itself have been induced by the method described herein. Complex patterns of induced cracks in the second layer of the layered material can be formed. A plurality of induced cracks in the second layer of the layered material can form a complex pattern of cracks.

The cracks induced by the method herein may be in addition to any pre-existing cracks in the second layer induced using other methods.

The cracks may be induced using a method that combines the electrical method proposed herein with other methods known in the art including mechanical indentation, nanoindentation, introduction of mechanical defects, notches, holes or stress raisers, mechanical bending, mechanical stretching, piezoelectric expansion and electrostrictive expansion.

### System

The present disclosure provides, in a third aspect, a system for inducing cracks in a thin film crystalline layer, the system comprising:
a. a layered material comprising a first layer and a second layer, wherein the second layer is disposed on the first layer, wherein the second layer is crystalline, (this second layer also being termed a thin film crystalline layer);
b. an electrode, to allow a potential difference to be applied at a location on the layered material to induce a crack in the second layer extending from a location on the second layer located closest to the location of the applied potential difference on the layered material.

Alternatively, the electrode may allow a potential difference to be applied at a location on the second layer, to induce a crack in the second layer extending from the location.

The system may comprise the layered material as part of an electronic circuit. The system may comprise the layered material and an electrode as part of an electronic circuit. The electrode may be on the layered material. The layered material may form part of the electronic circuit, wherein current can pass through the layered material. The layered material may form part of the electronic circuit, wherein current can pass through the second layer of the layered material. The electronic circuit may also comprise a power source. The power source may apply the voltage. The electronic circuit may comprise the layered material and an electrode. The electronic circuit may comprise a plurality of electrodes. The electronic circuit may further comprise components including, but not limited to, transistors, capacitors, batteries, switches, power sources, and wires.

The electrode may be located on a surface of the second layer or at an edge of the second layer. In an embodiment, a plurality of electrodes are disposed at locations selected from a surface of the second layer and an edge of the second layer. In an embodiment, two electrodes are disposed at locations selected from a surface of the second layer and an edge of the second layer. The potential difference may be applied between the electrodes to induce the crack.

The potential difference may be applied between the electrode on the surface of a non-electrically conducting second layer and an electrically conducting first layer to induce the crack in the second layer. The potential difference may be applied between the electrode on the surface of a non-electrically conducting second layer and an electrically conducting buffer layer on the first layer to induce the crack in the second layer.

The electrode may be located on a surface of the third layer. The potential difference may be applied between the electrode and a conducting second layer to induce the crack in the second layer. The potential difference may be applied between the electrode and the electrically conducting first layer to induce a crack in the second layer. The potential difference may be applied between the electrode and the electrically conducting buffer on the first layer to induce a crack in the second layer.

### Devices

The present disclosure provides a device comprising the layered material according to the second aspect, or the system according to the third aspect. The device may be an electronic device. The electronic devices may be, but are not limited to, a two-terminal fuse, a three-terminal PROM, a three-or four-terminal crack-based piezotransistor, a pressure/touch sensor, and a nanofluidic channel.

The presently disclosed subject matter can be further applied to the following non-limiting embodiments of electronic devices.

In a specific embodiment, the conductivity of the layered material can be tuned by the degree of crack opening in the conductive channel of the second layer. This may be used to modulate the current which passes through the layered material. This may be used to modulate the current in a device which comprises the layered material. In a specific embodiment, the degree of crack opening in the conductive channel of the second layer and hence conductivity of the conductive channel of the second layer can be tuned by replacing the electrically conducting second layer with a bilayer or tri-layer, wherein the second layer may comprise a bi-layer comprising an electrically conducting material and an insulator, and the insulator is disposed between the first layer and the electrically conducting material of the bi-layer.

In a specific embodiment, the degree of crack opening in the conductive channel of the second layer and hence conductivity of the conductive channel of the second layer can be tuned by replacing the electrically conducting second layer with a bilayer or tri-layer, wherein the second layer may comprise a bi-layer comprising an electrically conducting material and an insulator, and the electrically conducting material is disposed between the first layer and the insulator of the bi-layer.

In a specific embodiment which enhances the crack opening in the electrically conducting layer, therefore reducing the conductivity of the layered material, the second layer may comprise a tri-layer comprising a layer of electrically conducting material and two layers of insulators, wherein the electrically conducting material is disposed between the two insulating layers.

Examples of electronic devices will now be further described with reference to the accompanying non-limiting Figures in which:

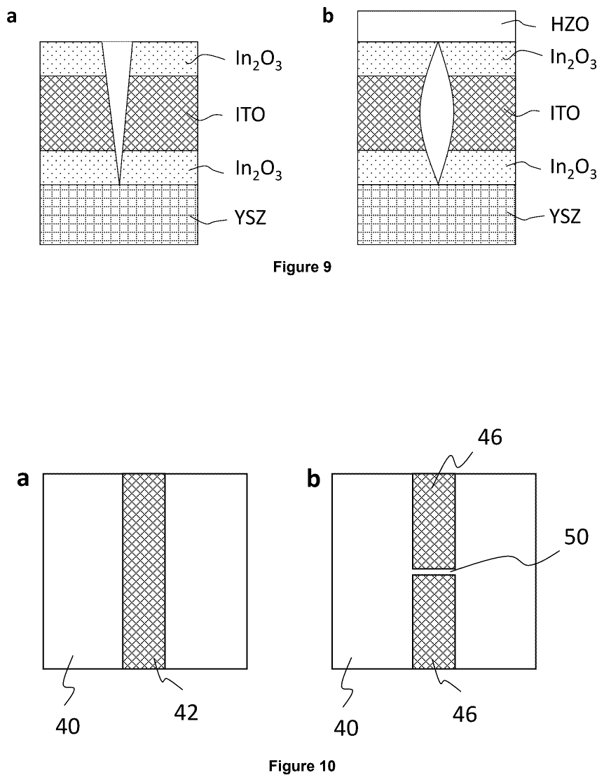

FIG. 9a shows an example where the first layer comprises YSZ and the second layer comprises a tri-layer, wherein the tri-layer comprises a conducting ITO layer between two highly resistive (semi-insulating) appropriately-doped In₂O₃ layers, wherein there is a crack in the second layer which extends through all three layers of the tri-layer, wherein the crack widens as it proceeds from the bottom semi-insulating layer (the In₂O₃ layer of the tri-layer which is disposed on the first layer of the layered material) to the top In₂O₃ semi-insulating layer. The degree of crack opening and hence conductivity of the ITO channel in the tri-layer of the second layer can be tuned.

While stoichiometric In₂O₃ is an insulator, unintentional doping can result in a doped In₂O₃ which is semiconducting. Intentional doping can compensate for this, resulting in a highly resistive (semi-insulating) doped In₂O₃, with resistivities up to about 10⁵ Ohm m.

FIG. 9b shows an example where the first layer comprises YSZ, the third layer comprises HZO and the second layer comprises a tri-layer, wherein the tri-layer comprises a conducting ITO layer between two highly resistive semi-insulating In₂O₃ layers, wherein there is a crack in the second layer which extends through all three layers of the tri-layer, wherein the crack widens as it proceeds away from the HZO/In₂O₃ interface and the In₂O₃/YSZ interface. The degree of crack opening and hence conductivity of the ITO channel in the tri-layer of the second layer can be tuned.

FIG. 10 shows an example of a two-terminal “fuse” which acts by passing a current above a certain value through a conducting second layer channel comprising for example strained ITO which leads to cracking of the channel resulting in increased resistance of the channel (reduction in current passing through the channel). The conducting second layer is disposed on the first layer, wherein the first layer is non-electrically conducting (for example YSZ), and the second layer is under tensile stress. When the current passing through the channel is above a certain value, a crack is induced in the channel resulting in increased resistance of the channel and therefore a reduction in current passing through the channel and therefore a reduction in current passing through the device in which it is incorporated. The device in this example, depicted in FIG. 10, comprises a first layer 40 (e.g. YSZ) and second layer 42 (e.g. strained ITO), wherein the second layer has been patterned into a channel. Passing a current above a certain critical value along the length of the channel leads to the formation of a crack 50 and increased resistance (reduction in current) through the cracked channel 46.

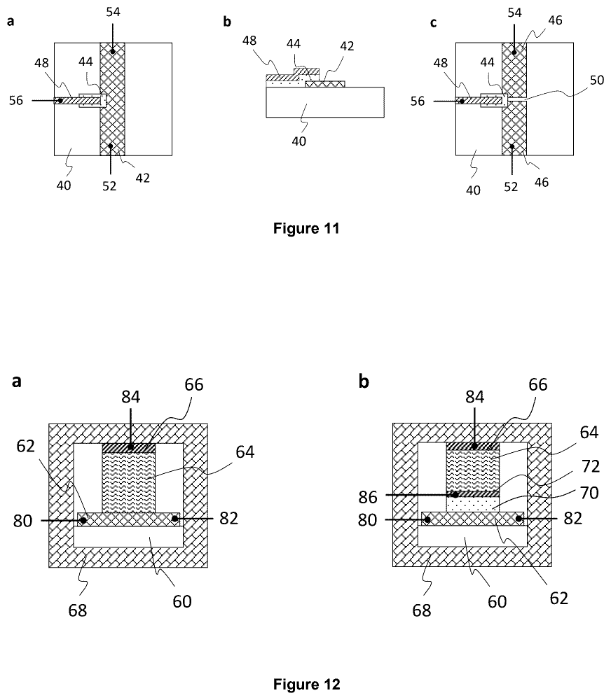

FIG. 11 shows an example of a three-terminal “PROM” (programmable read only memory) device, wherein the conducting second layer (e.g. ITO) is disposed on the first layer which is non-electrically conducting, wherein the second layer is patterned into a conducting channel, wherein the second layer has disposed thereon a gate, the gate comprising a gate insulator and a metallic gate electrode, wherein the gate insulator is disposed on the second layer and the metallic gate electrode is disposed on the gate insulator, wherein the second layer is a component of an electric circuit and current can pass through the second layer. The conducting channel is initially in the ON state as there is no crack in the conducting channel. Application of a potential difference between the gate and the channel induces a crack in the channel resulting in increased resistance of the channel and therefore a decrease in the current that passes through the circuit in which it is incorporated. Information as ON or OFF can therefore be stored in the device. The device in this example, depicted in FIG. 11, comprises a first layer 40 (e.g. YSZ or Si with YSZ buffer, a second layer 42 (e.g. ITO) which has been patterned into a channel, a gate insulator 44 (e.g. HZO) and an electrode 48 (e.g. elemental metal or TiN). Electrical connections 52 and 54 are used to drive a current by applying a potential difference between 52 and 54. Application of potential difference above a certain value between the electrode 48 and the channel 42 (e.g. by application of potential difference between connection 56 and connection 52 and/or 54) creates a crack 50 and a cracked channel 46 with a larger resistance. The uncracked channel corresponds to the ON state. Inducing a crack puts the device into the OFF state, allowing information to be stored. (a) Top view of the device before cracking, i.e. in the ON state. (b) Side view of the device. (c) Top view of the device after cracking, i.e. in the OFF state.

FIG. 12a shows an example of a three-terminal crack-based piezotransistor wherein a conducting second layer (e.g. ITO) is disposed on the first layer, wherein the second layer is part of an electronic circuit, wherein a piezoelectric is disposed on the second layer, wherein a top gate electrode is disposed on the piezoelectric, wherein all the layers are encapsulated by a high-stiffness low expansion/contraction material. Application of a voltage to the second layer induces a crack therein. Opening/closing of the induced crack in the second layer can be controlled by application of a voltage across the piezoelectric material via the top gate electrode. The cracked second layer acts as a piezoresistive element of the piezotransistor.

FIG. 12b shows an example of a four-terminal crack-based piezotransistor wherein the second layer is disposed on the first layer, wherein the second layer is part of an electronic circuit, wherein a dielectric is disposed on the second layer, wherein a metallic gate is disposed on the dielectric, wherein a piezoelectric is disposed on the metallic gate, wherein a top electrode is disposed on the piezoelectric, wherein all the layers are encapsulated by a high-stiffness low expansion/contraction material. Application of a voltage across the dielectric via the metallic gate induces a crack in the second layer. Opening/closing of the induced crack in the second layer can be controlled by applying a voltage across the piezoelectric. The cracked second layer acts as a piezoresistive element of the piezotransistor.

The devices in these examples, as depicted in FIG. 12, comprise a first layer 60 (e.g. YSZ or YSZ-buffered Si), second layer 62 (e.g. ITO), a piezoelectric layer 64 (e.g. PZT, PMN-PT, hafnia or HZO), an electrode 66 (e.g. elemental metal or TiN) located above the piezoelectric layer, a casing made of high-stiffness (low compliance) material 68, and electrical connections 80, 82 and 84. The second layer may be patterned into a channel. The four-terminal device in FIG. 12 additionally comprises a dielectric 70 (e.g. HZO or SiO₂) above the second layer, a second electrode 72 between the piezoelectric and dielectric layers, and electrical connection 86. The casing 68 encapsulates the active stack comprising 60, 62, 64, 66, 70 and 72, and restricts the overall expansion of the active stack when a potential difference is applied across the piezoelectric. A crack in the second layer may be induced during device fabrication electrically using the method herein. Alternatively, a crack in the second layer may be produced electrically after device fabrication. For example, in the three-terminal device, the crack in the second layer may be created by applying a potential difference between connections 80 and 82. In the four-terminal device, the crack in the second layer may be created by applying a potential difference between connection 86 and connection 80 and/or 82. Crack opening/closing is controlled by application of a potential difference across the piezoelectric, i.e. between connection 84 and connection 80 and/or 82 for the three-terminal device, and between connection 84 and connection 86 for the four-terminal device. Crack opening and closing modules the resistance of the second layer, i.e. it modules the current flowing through the second layer when a potential difference is applied between connections 80 and 82.

Other applications include, but are not limited to, pressure/touch sensors, nanofluidic channels, nanolithography, and templates for nanowire growth.

### EXAMPLES

The presently disclosed subject matter will be further described by reference to the following non-limiting Examples.

### Methods and Materials

### Sample Fabrication

The thin film crystalline layers were deposited using off-axis radio-frequency (rf) magnetron sputtering. Single crystal yttria-stabilised zirconia substrates (YSZ) with (001), (110), and (111) orientations were used as the growth templates. Prior to deposition, the substrates were cleaned in an acetone ultrasound bath for 3 mins, followed by 3 mins in an ethanol or isopropanol ultrasound bath. The substrates were then pasted on a resistive heater using vacuum compatible silver paste and inserted into the deposition chamber. The deposition chamber was pumped down to a pressure to approximately 10⁻⁶ mbar or less prior to introducing the processing gases. Indium tin oxide (ITO) films with thickness between 10 to 150 nm were grown at 700° C. in a 0.1 Torr atmosphere with an argon to oxygen ratio of 20:1 with rf power of 50 W from an In₂O₃—SnO₂ 90/10 wt % target. The films were characterised using X-ray diffraction and atomic force microscopy (AFM). Some of the ITO films were then cleaned using acetone and isopropanol ultrasound bath before being re-pasted on the heater with silver paste and reinserted into the growth chamber for growth of the Hf_{0.5}Zr_{0.5}O₂ (HZO) overlayer. HZO films with thicknesses from 5 to 40 nm were grown between 485 to 535° C. in a 0.18 Torr atmosphere with an argon to oxygen ratio of 28:20 with rf power of 60 W.

### Device Fabrication

Optical lithography was used to pattern the surface by spincoating photoresist S1818 baked at 115° C. for 60 seconds and then exposing it through a mask using a Suss MJB3 Mask Aligner. Capacitors with Pt electrodes were fabricated by sputtering Pt onto the patterned sample at room temperature in a 0.05 mbar argon atmosphere, followed by a conventional lift-off process. ITO films were patterned by argon ion milling or wet etching the ITO films using 37% HCl solution.

### Process for Inducing Cracks

For the cracks induced by atomic force microscope tips, a Bruker Dimension Icon microscope and silicon probes with a nominal tip radius of 25 nm and Pt/Ir conductive coating with stiffnesses of 0.2 Nm⁻¹ (CONTV-PT) and 3 Nm⁻¹ (SCM-PIT-V2) were used for the crack-inducing experiments. Several volts (3-10 V) were applied to a stationary tip or while scanning the tip across the surface, producing a topographical defect and an extended channel crack that can be visualised on the sample topography. Surface topography images were obtained in contact mode with a deflection setpoint of 0.5 V. For the cracks induced with macroscopic electrodes, the experiments were performed on the HZO/ITO//YSZ heterostructures with circular top Pt electrodes with the radius of 25 μm, 50 μm, and 100 μm, 3-7 V were applied between the Pt electrodes and bottom ITO layer using a Keithley 2636B sourcemeter.

### Channel Cracks

The method for producing channel cracks involves the growth of an epitaxial metallic thin film on a crystalline substrate with a smaller bulk lattice parameter such that a tensile stress is imposed on the film. For films above a certain thickness, which depends on the bulk lattice parameter mismatch between the film and substrate, the growth conditions and subsequent cooling conditions, the stress is relaxed through dislocation formation, surface roughening, cracking, or a combination thereof. For films below a certain thickness, the stress (or partial stress) can be sustained without relaxation. For such films, the present inventors have found that cracking can be induced in predetermined locations by creating a local defect through application of a sufficiently large electric field and/or current.

In a specific embodiment, an indium tin oxide (ITO) film is deposited epitaxially using off-axis radiofrequency magnetron sputtering from an In₂O₃—SnO₂ 90/10 wt % target on (100)-oriented yttria-stabilised zirconia (Y₂O₃:ZrO₂ or YSZ) single crystal substrate. Prior to deposition, the substrate was cleaned in an ultrasound bath of acetone, followed by an ultrasound bath in isopropanol at room temperature. During the deposition, the substrate is held at a temperature of 700° C. in an Ar/O₂ atmosphere of ratio 20:1 and total pressure of 100 mTorr. After deposition, the film is cooled to room temperature in the same Ar/O₂ atmosphere. X-ray diffraction measurements indicate that the ITO films are also (100) oriented and strained to the substrate lattice constant with minimal strain relaxation.

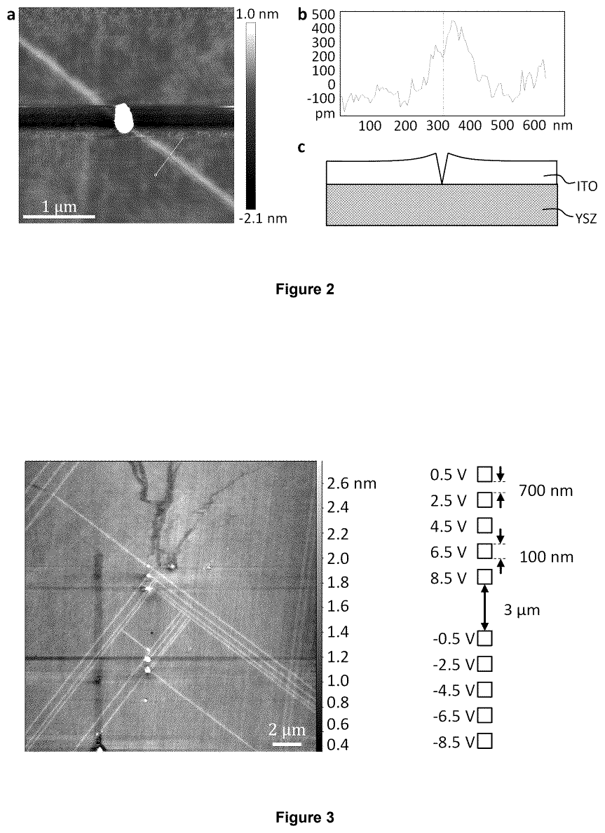

To create (write)/induce cracks, an atomic force microscope (AFM) tip with a radius of ten to a few tens of nm is used to apply voltages to the sample locally. Application of several volts to a stationary tip or while scanning the tip across the surface produces a topographical defect and an extended channel crack that can be visualized using the AFM as shown in FIGS. 2 and 3. In general, the voltage required to nucleate the crack will depend on the sample and tip type and condition. It was found that cracks always run along crystallographic directions aligned along one of two <110> cubic axes of the substrate, consistent with {110} cleavage planes of ITO.

In a specific embodiment, a channel crack was formed in the ITO thin film layer of a sample/layered material (which was prepared as described above) by applying 10 V for 10 seconds to an AFM tip positioned above the sample. FIG. 2 shows AFM topography after applying 10 V for 10 seconds to the tip positioned at the centre of the image. Application of voltage generates a topographical defect visible as a raised (bright) area in the centre of the image, and a channel crack running from top left to bottom right of the image. The opening of the crack can be seen as a thin dark line running through the centre of the crack and a small depression in the surface profile along the white line in (a) shown in (b). A schematic of the crack is shown in panel (c).

In a specific embodiment, a pattern of squares was written by applying different voltages while scanning an AFM tip over a 100 nm square area of a 26 nm thick ITO film on YSZ substrate. FIG. 3 shows the surface topography (imaged using AFM) after the pattern of squares was written. Voltages of either polarity with magnitude of 4.5 V or above were sufficient to produce a defect (visible as a bright feature with a large change of topography) and corresponding crack(s) running along or [−110] directions (visible as straight-line features with a height of <1 nm above the film surface. Cracks terminate when they encounter another crack.

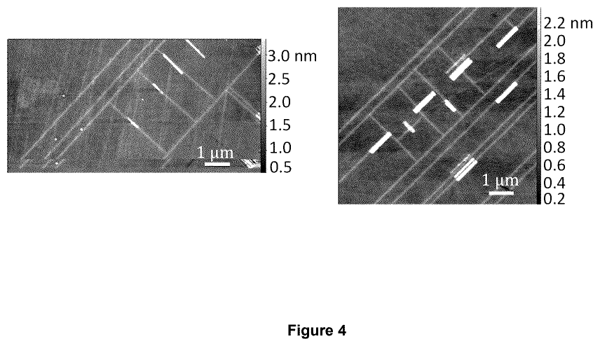

In order to induce cracks along a specific direction, the AFM tip can be scanned along that direction during the application of the voltage. In a specific embodiment, rastering the tip along the direction produces cracks predominantly along [110], while rastering along [−110] produces cracks predominantly along [−110]. This is shown in FIG. 4 where cracks were written by rastering the AFM tip along <110> directions while applying −5 to −7 V. Areas where the voltage was applied appear as bright rectangles corresponding to the areas of the highest topography. In most cases, induced cracks run parallel to the rastering direction. Image edges are approximately aligned with the crystallographic <100> directions.

### Tunnel cracks

Capping the metallic film with another material and then applying the above procedure can lead to formation of tunnel cracks. In a specific embodiment, ITO films on YSZ substrates were cleaned using acetone and isopropanol and a 9 nm thick hafnia-zirconia (HZO) epitaxial film was sputtered on top of the ITO film at a substrate temperature of 500° C., in an Ar/O₂ atmosphere with ratio 7:5 and total pressure of 180 mTorr. XRD measurements indicate that the film is mostly strained and has a mixture of monoclinic and orthorhombic-like phases with different orientations.

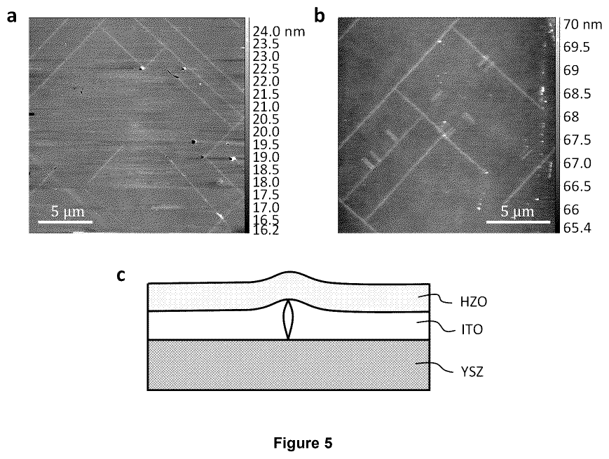

Applying −6 to −9 V between the bottom ITO layer and an AFM tip on the surface of the HZO leads to creation of tunnel cracks that appear as small protrusions in the surface of the HZO as shown in FIG. 5. The crack in the ITO layer does not seem to propagate into the HZO layer, which appears to be left intact. A lack of a thin dark line running through the central crack in FIG. 5b indicates the HZO layer is still left intact. The direction of the tunnel crack can be controlled by rastering the AFM tip along the <110> directions while applying the voltage.

In less defective films, the induced cracks propagate over large length scales, many tens of microns, while in more defective films, cracks can be arrested and subsequently their length can be extended by repeatedly scanning the AFM tip over the region containing the crack. In either case, crack propagation stops when the crack encounters another extended defect, e.g. another crack.

### Cracks Induced With Macroscopic Electrodes

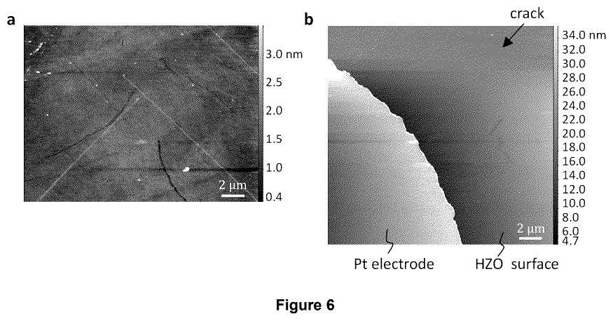

Alternatively, cracks can be induced by biasing a macroscopic Pt top electrode rather than a nanoscopic AFM tip. In a specific embodiment, to induce cracks, a circular Pt electrode (diameter=50 μm) was deposited on HZO (13.5 nm)/ITO (18 nm) heterostructure on (100)-oriented YSZ, and 6.5 V was applied between the Pt electrode and the ITO layer, contacted on the edge of the sample with silver paste. The cracks induced are shown in FIG. 6. FIG. 6a shows the induced cracks on the HZO surface, and FIG. 6b shows the top right region of the Pt electrode where the cracks formed.

### Cracks in Films of Other Crystallographic Orientation

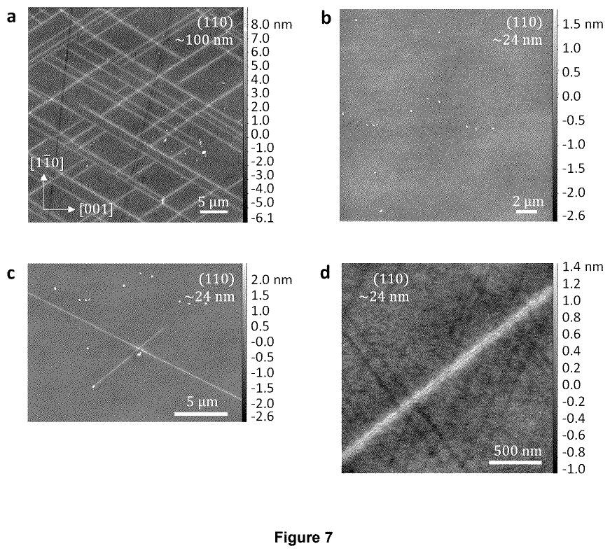

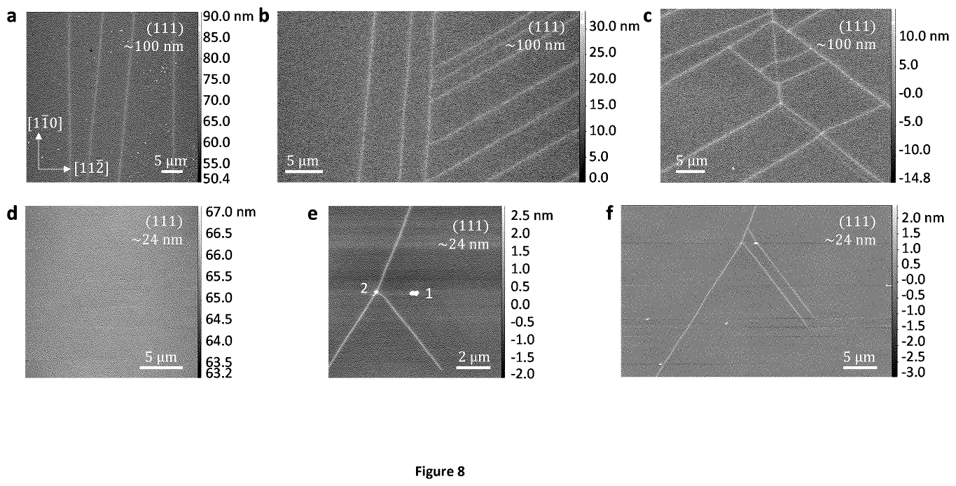

ITO thin films with intended thicknesses of approximately 106 nm and 23.5 nm were also grown on (110) and (111)-oriented YSZ substrates. Actual thicknesses may be different from the intended thicknesses, but for simplicity will be referred to as 100 nm and 24 nm films henceforth. Just like films on (100)-YSZ, the thicker films spontaneously cracked (FIGS. 7a and 8a-c), while thinner films only exhibit a cross-hatch-like topography (FIGS. 7b and 8d), which may be due to some strain relaxation through misfit dislocation formation. Application of bias to thinner films was found to induce cracks (FIG. 7c-d and 8e-f). In FIG. 8e-f, the application of bias at point 1 did not immediately nucleate a visible crack (FIG. 8e) but a crack is found to grow later (FIG. 8f) after repeated scanning of the tip over the same region (in the absence of applied bias).

### Devices

The presently disclosed subject matter can be further applied to the following non-limiting embodiments of electronic devices.

In a specific embodiment, the degree of crack opening and hence conductivity of ITO channel can be tuned by replacing single ITO layer with a bilayer or tri-layer of conducting ITO and e.g. highly resistive In₂O₃. This is illustrated in FIG. 9.

In a specific embodiment, the device is a two-terminal “fuse” which acts by passing a current above a certain value through a strained ITO channel which leads to cracking resulting in increased resistance (reduction in current). This is illustrated in FIG. 10.

In a specific embodiment, the device is a three-terminal “PROM” (programmable read only memory). A gate consisting of gate insulator and metallic gate electrode is used to create a crack in the ITO channel. The channel is initially in the ON state. Inducing a crack puts it into the OFF state, allowing information to be stored. This is illustrated in FIG. 11.

In a specific embodiment, the device is a three-terminal crack-based piezotransistor. In a specific embodiment the device is a four-terminal crack-based piezotransistor. These are shown in FIG. 12: (a) The crack is created in ITO by applying a potential difference between connections 80 and 82. Crack opening/closing controlled by application of potential difference across the piezoelectric via a top gate electrode using connection 84 and connections 80 and/or 82. The cracked ITO acts as a piezoresistive element of the piezotransistor. (b) The crack is created by applying a potential difference across a dielectric using the metallic gate using connection 86 and connections 80 and/or 82. Crack opening/closing controlled by applying a potential difference across the piezoelectric using connections 84 and 86. In both cases the system is encapsulated in high-stiffness low-expansion/contraction material.

Other applications include, but are not limited to, pressure/touch sensors, nanofluidic channels, nanolithography, and templates for nanowire growth.

### References Mentioned Herein or Otherwise Useful for Background

1. Huh, D., et al., Tuneable elastomeric nanochannels for nanofluidic manipulation. Nature Materials, 2007. 6(6): p. 424-428.
2. Kim, M., et al., Cracking-assisted fabrication of nanoscale patterns for micro/nanotechnological applications. Nanoscale, 2016. 8(18): p. 9461-9479.
3. Lee, T., et al., Transparent ITO mechanical crack-based pressure and strain sensor. Journal of Materials Chemistry C, 2016. 4(42): p. 9947-9953.
4. Adelung, R., et al., Strain-controlled growth of nanowires within thin-film cracks. Nature Materials, 2004. 3(6): p. 375-379.
5. Rodriguez, L., et al., Self-Pixelation Through Fracture in VO2Thin Films. Acs Applied Electronic Materials, 2020. 2(5): p. 1433-1439.
6. Liu, Z. Q., et al., Electrically reversible cracks in an intermetallic film controlled by an electric field. Nature Communications, 2018. 9.
7. Mills, K. L., et al., Instantaneous fabrication of arrays of normally closed, adjustable, and reversible nanochannels by tunnel cracking. Lab on a Chip, 2010. 10(12): p. 1627-1630.
8. Peng, C., et al., In situ electro-mechanical experiments and mechanics modeling of tensile cracking in indium tin oxide thin films on polyimide substrates. Journal of Applied Physics, 2011. 109(10).
9. Nam, K. H., I. H. Park, and S. H. Ko, Patterning by controlled cracking. Nature, 2012. 485(7397): p. 221-224.
10. Kamei, M., Y. Shigesato, and S. Takaki, Origin of Characteristic Grain-Subgrain Structure of Tin-Doped Indium Oxide-Films. Thin Solid Films, 1995. 259(1): p. 38-45.

The present disclosure may also be described by one or more of the following paragraph(s) “para” (s)
1. A method of inducing a crack in a thin film crystalline layer, the method comprising
   a. providing a layered material comprising a first layer and a second layer, wherein the second layer is disposed on the first layer, wherein the second layer is crystalline and is under tensile stress (this second layer also being termed a thin film crystalline layer),
   b. applying a potential difference between an electrode and the layered material to induce a crack extending from a location on the second layer located closest to the electrode.
2. A layered material comprising a first layer and a second layer, wherein the second layer is disposed on the first layer, wherein the second layer is crystalline (this second layer also being termed a thin film crystalline layer),
   wherein the second layer has a crack therein, the crack having been induced by applying a potential difference at a location on the layered material while the second layer is under tensile stress.
3. A system for inducing cracks in a thin film crystalline layer, the system comprising:
   a. a layered material comprising a first layer and a second layer, wherein the second layer is disposed on the first layer, wherein the second layer is crystalline and is under tensile stress (this second layer also being termed a thin film crystalline layer);
   b. an electrode, to allow a potential difference to be applied at a location on the layered material to induce a crack in the second layer extending from a location on the second layer located closest to the location of the applied potential difference on the layered material.
4. The method according to para 1, the layered material according to para 2, and the system according to para 3, wherein the second layer comprises a crystalline material with a thickness below a critical thickness for crack formation.
5. The method, the layered material, and the system according to any preceding para, wherein the second layer comprises a crystalline electrically conducting material.
6. The method, the layered material, and the system according to para 5, wherein the second layer comprises a wide band gap semiconductor.
7. The method, the layered material, and the system according to any preceding para, wherein the second layer comprises a material selected from an oxide and a nitride.
8. The method, the layered material, and the system according to any preceding para, wherein the second layer comprises a material selected from ITO, In₂O₃, VO₂, V₂O₃, Fe₂O₃, Fe₃O₄, MoO₃, MoO₂ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN.
9. The method, the layered material, and the system according to any preceding para, wherein the second layer comprises ITO.
10. The method, the layered material, and the system according to any preceding para, wherein the second layer is epitaxially grown on the first layer.
11. The method, the layered material, and the system according to any preceding para, wherein the second layer is no greater than 80 nm in thickness.
12. The method, the layered material, and the system according to any preceding para, wherein the second layer is from about 5-50 nm in thickness.
13. The method, the layered material, and the system according to any preceding para, wherein the tensile stress in the second layer is due to a difference in bulk lattice parameter between the first layer and the second layer.
14. The method, the layered material, and the system according to para 13, wherein the tensile stress in the second layer is due to the second layer having a smaller bulk lattice parameter than the first layer.
15. The method, the layered material, and the system according to any preceding para, wherein the first layer comprises a crystalline material.
16. The method, the layered material, and the system according to any preceding para, wherein the first layer comprises a crystalline non-electrically conducting material.
17. The method, the layered material, and the system according to any preceding para, wherein the first layer comprises a material selected from an inorganic material and a polymeric material.
18. The method, the layered material, and the system according to para 17, wherein the inorganic material comprises a ceramic.
19. The method, the layered material, and the system according to any preceding para, wherein the first layer comprises an oxide.
20. The method, the layered material, and the system according to any preceding para, wherein the first layer comprises a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF.
21. The method, the layered material, and the system according to any preceding para, wherein the first layer comprises YSZ.
22. The method, the layered material, and the system according to any preceding para, wherein a third layer is disposed on the second layer.
23. The method and the layered material according to para 22, wherein the induced crack in the second layer, formed by application of the potential difference between the electrode and the layered material, does not penetrate fully through the third layer.
24. The method, the layered material, and the system according to paras 22 and 23, wherein the third layer comprises a material selected from an inorganic material and a polymeric material.
25. The method, the layered material, and the system according to paras 22, 23 and 24, wherein the third layer comprises a material selected from HZO, HfO₂, ZrO₂ and YSZ.
26. The method, the layered material, and the system according to any preceding para, wherein the third layer comprises HZO.
27. The method and the layered material according to any preceding para, wherein the potential difference applied is between 0.5-10 V of either polarity.
28. The method and the layered material according to any preceding para, wherein the potential difference is applied for no greater than 15 seconds.
29. The method and the system according to any preceding para, wherein the electrode is moved during application of the potential difference.
30. The method according to para 29, wherein the induced crack is formed in the direction of the movement of the electrode during application of the potential difference.
31. The method and the system according to any preceding para, wherein the electrode is selected from a microscopic electrode and a macroscopic electrode.
32. The method and the system according to para 28, wherein the microscopic electrode has a dimension of from about 1-500 nm.
33. The method and the system according to para 28, wherein the macroscopic electrode has a dimension of from about 1-1000 μm.
34. An electronic device comprising the layered material according to paras 2, and 4-28, or a system according to paras 3-22, 24, 25, 26, 29, 32, and 33.
35. The electronic device according to para 34, wherein the electronic device has at least one electrode disposed across the layered material, and the layered material is a component of an electronic circuit, wherein when the induced crack is formed it reduces or prevents the flow of electricity along the component of the electronic device that the layered material forms part of.
36. The electronic device according to para 34 and 35, wherein the electronic device is selected from a two-terminal fuse, a three-terminal PROM, a three-or four-terminal crack-based piezotransistor, a pressure/touch sensor, and a nanofluidic channel.

1. A method of inducing a crack in a thin film crystalline layer, the method comprising
a. providing a layered material comprising a first layer and a second layer, wherein the second layer is disposed on the first layer, wherein the second layer is crystalline and is under tensile stress (this second layer also being termed a thin film crystalline layer),
b. applying a potential difference between an electrode and the layered material to induce a crack extending from a location on the second layer located closest to the electrode.

2. The method according to claim 1, wherein the second layer comprises a crystalline material with a thickness below a critical thickness for crack formation.

3. The method according to claim 1, wherein the second layer comprises a crystalline electrically conducting material.

4. The method, according to claim 1, wherein the second layer comprises a material selected from ITO, In₂O₃, VO₂, V₂O₃, Fe₂O₃, Fe₃O₄, MoO₃, MoO₂ZnO, SnO₂, TiO₂, Al₂O₃, aluminium-doped ZnO (AZO), indium-doped cadmium oxide, gallium-doped zinc oxide, fluorine-doped tin oxide (FTO), indium-doped zinc oxide, graphite, graphene, graphene oxide, LaAlO₃, SrTiO₃, Nb—SrTiO₃, BaSnO₃, lanthanum strontium manganite (LSMO), SrRuO₃, WO₃, GaN, Zn₃N₂, CaZn₂N₂, Cu₃N, TiN, ZrN, HfN, NbN, VN, and TaN.

5. The method according to claim 1, wherein the second layer is epitaxially grown on the first layer.

6. The method according to claim 1, wherein the tensile stress in the second layer is due to the second layer having a smaller bulk lattice parameter than the first layer.

7. The method according to claim 1, wherein the first layer comprises a crystalline material.

8. The method according to claim 1, wherein the first layer comprises a material selected from an inorganic material and a polymeric material.

9. The method according to claim 1, wherein the first layer comprises a material selected from yttria-stabilised zirconia (YSZ), CeO₂, Al₂O₃, BaO, SrTiO₃, KTaO₃, KNbO₃, BaTiO₃, barium strontium titanate (BST), BaZrO₃, PbTiO₃, lead zirconate titanate (PZT), lead magnesium niobate lead titanate (PMN-PT), LaSrAlO₄, TiO₂, ZrO₂, MgO, LaAlO₃ (LAO), Gd₃Ga₅O₁₂, Ga₂O₃ lanthanum strontium aluminium tantalate (LSAT), niobium-doped strontium titanate (Nb—SrTiO₃), SrRuO₃, CaRuO₃, NdGaO₃, NdAlO₃, YAlO₃, LiNbO₃, LiTaO₃, DyScO₃, GdScO₃, NdScO₃, LaLuO₃, SiO₂, Si, Ge, GaAs, and LiF.

10. The method according to claim 1, wherein a third layer is disposed on the second layer, wherein the induced crack in the second layer, formed by application of the potential difference between the electrode and the layered material, does not penetrate fully through the third layer.

11. The method according to claim 1, wherein a third layer is disposed on the second layer, wherein the third layer comprises a material selected from an inorganic material and a polymeric material.

12. The method according to claim 11, wherein the third layer comprises a material selected from HZO, HfO₂, ZrO₂ and YSZ.

13. The method according to claim 1, wherein the potential difference applied is between 0.5-10 V of either polarity.

14. The method according to claim 1, wherein the electrode is moved during application of the potential difference.

15. The method according to claim 14, wherein the induced crack is formed in the direction of the movement of the electrode during application of the potential difference.

16. A layered material comprising a first layer and a second layer, wherein the second layer is disposed on the first layer, wherein the second layer is crystalline (this second layer also being termed a thin film crystalline layer),
wherein the second layer has a crack therein, the crack having been induced by applying a potential difference at a location on the layered material while the second layer is under tensile stress.

17. An electronic device comprising the layered material according to claim 16.

18. An electronic device according to claim 17, wherein the electronic device has at least one electrode disposed across the layered material, and the layered material is a component of an electronic circuit, wherein when the induced crack is formed it reduces or prevents the flow of electricity along the component of the electronic device that the layered material forms part of.

19. An electronic device according to claim 18, wherein the electronic device is selected from a two-terminal fuse, a three-terminal PROM, a three-or four-terminal crack-based piezotransistor, a pressure/touch sensor, and a nanofluidic channel.

20. A system for inducing cracks in a thin film crystalline layer, the system comprising:
a. a layered material comprising a first layer and a second layer, wherein the second layer is disposed on the first layer, wherein the second layer is crystalline and is under tensile stress (this second layer also being termed a thin film crystalline layer); and
b. an electrode, to allow a potential difference to be applied at a location on the layered material to induce a crack in the second layer extending from a location on the second layer located closest to the location of the applied potential difference on the layered material.
